(19) United States
(12) Patent Application Publication
(10) Pub. No.: US 2025/0084532 A1
(43) Pub. Date: Mar. 13, 2025

(54) HYBRID DEPOSITING APPARATUS FOR GALLIUM OXIDE AND METHOD FOR HYBRID DEPOSITING USING SAME

(71) Applicant: NEXUSBE CO., LTD, Jeonju-si Jeollabuk-do (KR)

(72) Inventors: Sung Hwan JANG, Hwaseong-si Gyeonggi-do (KR); Sang Hun KIM, Gwangju-si Gyeonggi-do (KR); Keun Sik KIM, Yongin-si Gyeonggi-do (KR); Byeong Yeol JANG, Yongin-si Gyeonggi-do (KR); Sang Hee WON, Pyeongtaek-si Gyeonggi-do (KR); Ho Young PARK, Yongin-si Gyeonggi-do (KR); Sang Gyun KIM, Incheon (KR); Hag Young CHOI, Yongin-si Gyeonggi-do (KR)

(73) Assignee: NEXUSBE CO., LTD, Jeonju-si Jeollabuk-do (KR)

(21) Appl. No.: 18/954,841

(22) Filed: Nov. 21, 2024

Related U.S. Application Data
(63) Continuation of application No. PCT/KR2023/017367, filed on Nov. 2, 2023.

(30) Foreign Application Priority Data
Nov. 7, 2022 (KR) 10-2022-0147199
Nov. 1, 2023 (KR) 10-2023-0149422

(51) Int. Cl. C23C 16/40; C23C 16/18; C23C 16/44; C23C 16/455; C23C 16/52

(52) U.S. Cl. CPC C23C 16/40; C23C 16/18; C23C 16/4408; C23C 16/45574; C23C 16/52

(57) ABSTRACT

The present disclosure relates to a hybrid deposition apparatus for gallium oxide, and a hybrid deposition apparatus for gallium oxide according to a disclosed embodiment of the present disclosure includes a gas supply assembly for supplying a source gas, a reaction gas, and a purge gas, a liquid supply assembly for supplying at least a portion of the source gas, and a chamber unit which is connected to the gas supply assembly and the liquid supply assembly and has a substrate disposed therein.

### CROSS-REFERENCE TO RELATED APPLICATIONS

This application is a continuation of International Application No. PCT/KR2023/017367 filed on Nov. 2, 2023, which claims priority to Korean Patent Application No. 10-2022-0147199 filed on Nov. 7, 2022 and Korean Patent Application No. 10-2023-0149422 filed on Nov. 1, 2023, the entire contents of which are herein incorporated by reference.

### TECHNICAL FIELD

The present disclosure relates to a hybrid deposition apparatus for gallium oxide and a method for hybrid depositing using the same, and more specifically, the present disclosure relates to a hybrid deposition apparatus for gallium oxide to which at least two deposition methods are applied and a method for hybrid depositing using the same.

### BACKGROUND ART

As electronic products used in real life become increasingly sophisticated, the performance and number of semiconductors required to operate the electronic products tend to increase. Meanwhile, with the development of electric vehicle (EV) driving systems, high voltage systems are required, and power semiconductors with high band gaps are required.

Therefore, silicon (Si) was used as a wafer to produce conventional semiconductors, but silicon (Si) had problems of a low bandgap and limited high voltage implementation. To solve these problems, there are various attempts to manufacture semiconductor wafers using next-generation materials such as silicon carbide (SiC), gallium nitride (GaN), and gallium oxide (Ga₂O₃).

Generally, methods for depositing a thin film of a predetermined thickness on a substrate such as a semiconductor substrate or glass include physical vapor deposition (PVD) methods using physical collisions such as sputtering, chemical vapor deposition (CVD) methods using chemical reactions, etc. Among the chemical vapor deposition methods, a metal-organic chemical vapor deposition (MOCVD) method is a method of forming a thin film by flowing an organic metal complex gas onto a substrate and causing a decomposition reaction on the surface of the substrate, while Mist-CVD is a method of depositing a thin film through a chemical reaction with the substrate by spraying an aqueous solution at normal pressure. Recently, an atomic layer deposition (ALD) method, which can form fine patterned thin films of semiconductor devices, is also being considered as one of effective deposition methods.

However, each deposition method has advantages and disadvantages, and when a single deposition method is used, it has disadvantages of the corresponding deposition method. For example, the Mist-CVD method has problems in that it is difficult to control the growth rate of crystals (thin films) growing on a substrate and has low uniformity. The ALD method has excellent thin film characteristics, but has the disadvantage of a slow crystal growth rate, and the MOCVD method has a problem of low thin film characteristics instead of fast crystal growth rate.

In addition, since each of the deposition methods used to deposit thin films has different deposition conditions for stable deposition of the source gas or source liquid on the substrate, there has been a problem of making it impossible to properly utilize various deposition methods with existing deposition equipment.

There is a demand for the development of a deposition apparatus for solving the respective problems of the deposition methods as mentioned above and a deposition method using the same.

### DISCLOSURE

### Technical Problem

In order to solve the above-described problems, the present disclosure provides a hybrid deposition apparatus for gallium oxide that manufactures a wafer by forming a crystal layer using at least two deposition methods and a method for hybrid depositing using the same.

### Technical Solution

A hybrid deposition apparatus for gallium oxide according to a disclosed embodiment of the present disclosure includes a gas supply assembly for supplying a source gas, a reaction gas, and a purge gas, a liquid supply assembly for supplying at least a portion of the source gas, and a chamber unit which is connected to the gas supply assembly and the liquid supply assembly and has a substrate disposed therein.

Furthermore, the gas supply assembly may include a source gas supply module for supplying the source gas, a reaction gas supply module for supplying the reaction gas, a purge gas supply module for supplying the purge gas, and a main pumping module for providing negative pressure.

Furthermore, the source gas supply module includes a first source gas supply unit supplying a first source gas, and a second source gas supply unit supplying a second source gas different from the first source gas, and at least one of the first source gas and the second source gas may include trimethyl gallium (TMG).

Furthermore, the reaction gas supply module is disposed to be connected to the purge gas supply module, and the reaction gas supply module may receive oxygen (O₂) from the outside to generate ozone (O₃) and supply it to the chamber unit.

Furthermore, the reaction gas supply module may adjust the ratio of gallium supplied from the source gas supply module and the liquid supply assembly to ozone supplied to the chamber unit.

Furthermore, the liquid supply assembly may include a source liquid supply unit that supplies a source liquid, and an evaporation unit that atomizes the source liquid.

Furthermore, the gas supply assembly and the liquid supply assembly are coupled to the upper side of the chamber unit, and the source gas, reaction gas, purge gas supplied from the gas supply assembly, or the source liquid supplied from the liquid supply assembly may be injected vertically toward one surface of the substrate disposed inside the chamber unit.

Furthermore, it may include an injection unit including a plurality of injection nozzles which are formed inside the chamber unit and connected to the gas supply assembly and the liquid supply assembly to inject at least one of the source gas, the reaction gas, the purge gas, and the source liquid onto one surface of the substrate.

Furthermore, the hybrid deposition apparatus for gallium oxide according to the disclosed embodiment of the present disclosure may further include a substrate adjustment unit that supports a lower portion of the substrate and rotates the substrate in one direction.

Furthermore, the hybrid deposition apparatus for gallium oxide according to the disclosed embodiment of the present disclosure may further include a heating unit which is formed on the bottom of the substrate adjustment unit and adjusts temperatures inside the substrate and the chamber unit.

Furthermore, the substrate adjustment unit may adjust the position of the substrate within the chamber unit by elevating the substrate.

Furthermore, the substrate adjustment unit prepares the substrate in a first state in order to deposit a first layer on the substrate by a first deposition method, the substrate adjustment unit elevates the substrate and moves it to a first height, the heating unit heats the substrate to a first temperature range, the first deposition method includes an atomic layer deposition method, and the first layer may be an amorphous buffer layer.

Furthermore, the substrate adjustment unit prepares the substrate in a second state in order to deposit a second layer on the first layer by a second deposition method, the substrate adjustment unit lowers the substrate and moves the substrate to a second height, the heating unit heats the substrate to a second temperature range, the second deposition method includes a metal-organic chemical vapor deposition method, the second layer is a single crystal layer, the second height is formed to be greater than the first height, and the second temperature range may be formed to be higher than the first temperature range.

Furthermore, the gas supply assembly and the liquid supply assembly may operate selectively to grow a plurality of layers on the substrate through at least two of an atomic layer deposition (ALD) method, a metal-organic chemical vapor deposition (MOCVD) method, and a mist-chemical vapor deposition (Mist-CVD) method.

Meanwhile, a method for hybrid depositing using the hybrid deposition apparatus for gallium oxide according to the disclosed embodiment of the present disclosure includes a substrate preparation step of disposing a substrate to be grown inside a chamber unit, a first layer deposition step of depositing a first layer on the substrate by any one of the gas supply assembly and the liquid supply assembly, and a second layer deposition step of depositing a second layer on the first layer by any one of the gas supply assembly and the liquid supply assembly, and the first layer and the second layer may be deposited through different deposition methods.

Furthermore, the first layer deposition step may be performed by an atomic layer deposition (ALD) method, which is a first deposition method, and the second layer deposition step may be performed by any one of a metal-organic chemical vapor deposition (MOCVD) method and a mist-chemical vapor deposition (Mist-CVD) method, which are second deposition methods.

Furthermore, the method for hybrid depositing using the hybrid deposition apparatus for gallium oxide according to the disclosed embodiment of the present disclosure may further include a first layer deposition preparation step of preparing the substrate in a first state, which is the optimal condition for the first deposition method, by the substrate adjustment unit before the first layer deposition step, and a second layer deposition preparation step of preparing the substrate in a second state, which is the optimal condition for the second deposition method, by the substrate adjustment unit before the second layer deposition step.

Furthermore, the first state includes at least one of a first height and a first temperature range, the second state includes at least one of a second height and a second temperature range, the second height is formed to be greater than the first height, and the second temperature range may be formed to be higher than the first temperature range.

Furthermore, it may further include a third layer deposition step of depositing a third layer on the second layer by the liquid supply assembly, and the third layer deposition step may be performed by a mist-chemical vapor deposition method.

### Advantageous Effects

According to the disclosed embodiment of the present disclosure, since gallium oxide thin film crystals can be grown and deposited on the substrate 900, there is an advantage capable of manufacturing an integrated high-voltage, high-output semiconductor with a high bandgap compared to existing silicon semiconductors.

In addition, there is an advantage capable of manufacturing a semiconductor that meets the required specifications by using a hybrid deposition apparatus for gallium oxide that can apply various deposition methods when manufacturing a semiconductor using gallium oxide as a material, and a method for hybrid depositing.

In addition, there is an advantage of being able to compensate for the shortcomings of each deposition method by using a hybrid deposition apparatus for gallium oxide that can apply various deposition methods, and a method for hybrid depositing.

In addition, there are advantages in that plural deposition methods can be used in one apparatus, and layers can be stably deposited and grown on a substrate under optimal conditions of each deposition method by allowing the state of the substrate to be changed in one hybrid deposition apparatus for gallium oxide and a method for hybrid depositing so that various deposition methods can be applied.

### DESCRIPTION OF DRAWINGS

FIG. 1 is a schematic perspective view of a hybrid deposition apparatus for gallium oxide according to a disclosed embodiment of the present disclosure.

FIG. 2 is a conceptual diagram of a hybrid deposition apparatus for gallium oxide according to the disclosed embodiment of the present disclosure.

FIG. 3 is a schematic drawing for illustrating an injection unit, which is a component of a hybrid deposition apparatus for gallium oxide according to the disclosed embodiment of the present disclosure.

FIGS. 4A through 4D show various examples of gallium oxide thin films grown using a hybrid deposition apparatus for gallium oxide according to the disclosed embodiment of the present disclosure.

FIG. 5 is a schematic flowchart of a method for hybrid depositing using a hybrid deposition apparatus for gallium oxide according to the disclosed embodiment of the present disclosure.

FIG. 6 is a conceptual diagram of a hybrid deposition apparatus for gallium oxide according to another embodiment of the present disclosure.

FIG. 7 is a diagram for explaining a process of preparing a substrate in a first state in order to deposit a first layer by a first deposition method in a hybrid deposition apparatus for gallium oxide according to another embodiment of the present disclosure.

FIG. 8 is a diagram for explaining a process of preparing a substrate in a second state in order to deposit a second layer by a second deposition method in a hybrid deposition apparatus for gallium oxide according to another embodiment of the present disclosure.

FIG. 9 is a schematic flowchart of a method for hybrid depositing using a hybrid deposition apparatus for gallium oxide according to another embodiment of the present disclosure.

### EXPLANATION OF REFERENCE NUMERALS

1: hybrid deposition apparatus for gallium oxide 100: gas supply assembly
110: source gas supply module 120: reaction gas supply module
130: purge gas supply module 140: main pumping module
200: liquid supply assembly 210: source liquid supply unit
220: evaporation unit 300: chamber unit
400: injection unit 500: susceptor
600, 600′: substrate adjustment unit 700: heating unit
S110: substrate preparation step S120: first layer deposition step
S130: second layer deposition step S140: third layer deposition step
S210: substrate preparation step S220: first layer deposition preparation step
S230: first layer deposition step S240: cleaning step
S250: second layer deposition preparation step S260: second layer deposition step

### Best Model

The advantages and features of the present disclosure and methods for achieving them will become clear by referring to the embodiments described in detail below along with the accompanying drawings. However, the present disclosure is not limited to the embodiments disclosed below and will be implemented in various different forms. The present embodiments only serve to ensure that the disclosure of the present disclosure is complete and are provided to completely inform those skilled in the art to which the present disclosure pertains of the scope of the invention, and the present disclosure is only defined by the scope of the claims.

Although first, second, etc. are used to describe various components, these components are of course not limited by these terms. These terms are merely used to distinguish one component from another. Therefore, it goes without saying that the first component mentioned below may also be a second component within the technical spirit of the present disclosure.

The same reference numerals refer to the same components throughout the specification.

The respective features of the various embodiments of the present disclosure can be partially or fully coupled to or combined with each other, and as can be fully understood by those skilled the art, in various technical interconnections and operations are possible, each embodiment can be implemented independently of each other, and it may be possible to conduct them together due to a related relationship.

Meanwhile, provisional effects that can be expected from technical features of the present disclosure that are not specifically mentioned in the specification of the present disclosure are treated as if described in the present specification, and since the present embodiment is provided to more completely explain the present disclosure to those skilled in the art, the content shown in the drawings may be exaggeratively expressed compared to the actual implementation of the invention, and the detailed description of the configuration that is judged to unnecessarily obscure the gist of the present disclosure is omitted or described briefly.

Hereinafter, the disclosed embodiments of the present disclosure will be described in detail with reference to the accompanying drawings.

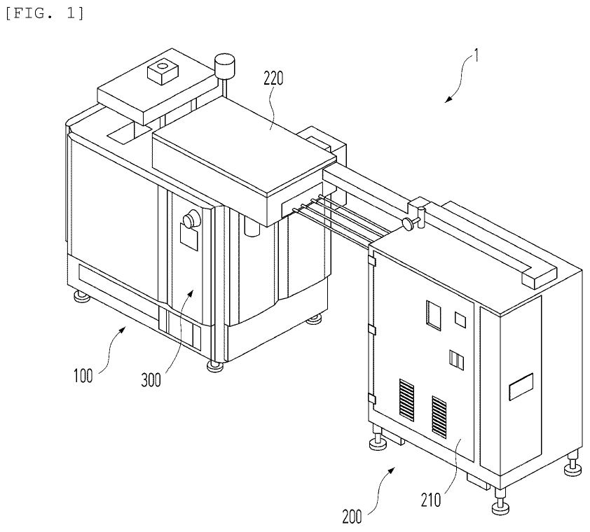

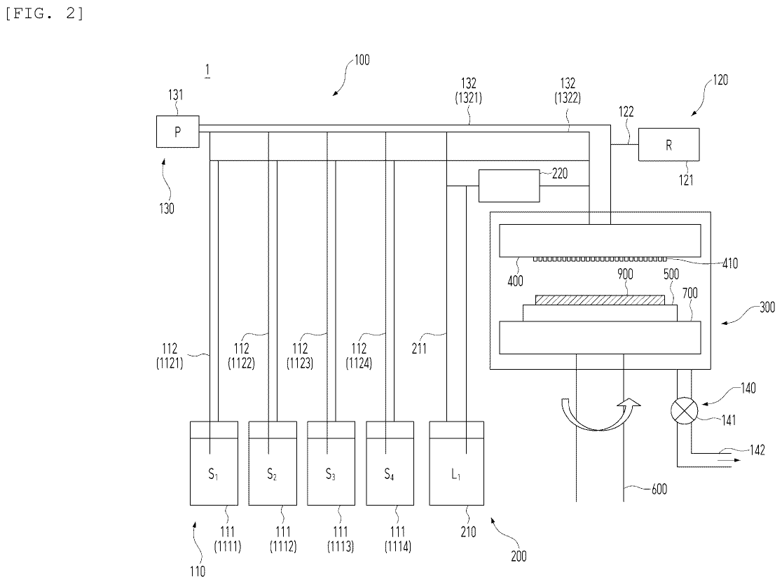

FIG. 1 is a schematic perspective view of a hybrid deposition apparatus 1 for gallium oxide according to a disclosed embodiment of the present disclosure, and FIG. 2 is a conceptual diagram of a hybrid deposition apparatus 1 for gallium oxide according to the disclosed embodiment of the present disclosure.

Referring to FIG. 1, the hybrid deposition apparatus 1 for gallium oxide according to the disclosed embodiment of the present disclosure includes a gas supply assembly 100, a liquid supply assembly 200, and a chamber unit 300. The gas supply assembly 100 may supply various types of gas to the chamber unit 300. Illustratively, the gas supply assembly 100 may supply source gas for growing crystals on a substrate 900. In addition, the gas supply assembly 100 may supply a reaction gas for reacting with the source gas that is supplied to grow crystals on the substrate 900. In addition, the gas supply assembly 100 may supply a purge gas for preventing unintentional diffusion of the source gas inside the chamber unit 300.

Hereinafter, the gas supply assembly 100 will be described in more detail. The gas supply assembly 100 may include a source gas supply module 110 for supplying source gas, a reaction gas supply module 120 for supplying a reaction gas, and a purge gas supply module 130 for supplying a purge gas. The source gas supply module 110 may supply source gases (S₁, S₂, S₃, and S₄) stored in a source gas supply unit 111 to the chamber unit 300 through a source gas supply line 112.

The source gas supply module 110 may supply at least one of the source gases (S₁, S₂, S₃, and S₄) to the chamber unit 300. That is, the source gas supply module 110 may include at least one source gas supply unit 111, and the source gas supply module 110 may include a first source gas supply unit 1111 that supplies a first source gas S₁ and a second source gas supply unit 1112 that supplies a second source gas S₂. The second source gas S₂ may be a material that is different from the first source gas S₁. Illustratively, at least one of the first source gas S₁ and the second source gas S₂ may include trimethyl gallium (TMG). Since at least one of the various source gases (S₁, S₂, S₃, and S₄) contains a material containing gallium (Ga), a gallium oxide (Ga₂O₃) crystal can be deposited on the substrate 900.

For example, the source gas supply module 110 may include a first source gas supply unit 1111, a second source gas supply unit 1112, a third source gas supply unit 1113, and a fourth source gas supply unit 1114. At this time, the first source gas S₁ supplied to the chamber unit 300 by the first source gas supply unit 1111 may be trimethyl gallium (TMG), and the second source gas S₂ supplied to the chamber unit 300 by the second source gas supply unit 1112 may be trimethyl aluminum (TMA). When the second source gas S₂ is trimethyl aluminum (TMA), the lattice mismatch (layer mismatch) state can be resolved by depositing plural layers of aluminum gallium oxide (AlGaOₓ) with different textures.

In addition, the third source gas S₃ supplied to the chamber unit 300 by the third source gas supply unit 1113 may be DTMASn or BTBAS, and the fourth source gas S₄ supplied to the chamber unit 300 by the fourth source gas supply unit 1114 may be a material that becomes an additional material needed to manufacture a semiconductor wafer. In this way, the process of growing a thin film crystal on the substrate 900 may be optimized by providing the various source gases (S₁, S₂, S₃, and S₄) by the source gas supply unit 111.

The reaction gas supply module 120 may supply a reaction gas (R) to the chamber unit 300. For example, the reaction gas (R) may be ozone (O₃), and the reaction gas supply unit 121 of the reaction gas supply module 120 may receive oxygen (O₂) from the outside and generate ozone (O₃) to supply it to the chamber unit 300. Ozone (O₃) supplied by the reaction gas supply module 120 may react with gallium (Ga) supplied by the source gas supply module 110 and/or the liquid supply assembly 200, and gallium oxide (Ga₂O₃) generated by the chemical reaction of gallium (Ga) and ozone (O₃) may be deposited on the substrate 900.

Meanwhile, in order to generate the required amount of gallium oxide (Ga₂O₃), the supply ratio of gallium (Ga) and ozone (O₃) must be adjusted. Accordingly, the reaction gas supply module 120 may adjust the ratio of gallium supplied from the source gas supply module 110 to ozone supplied to the chamber unit 300. The ratio of gallium to ozone may be determined by the degree to which the reaction gas supply control valve (not shown) formed between the reaction gas supply unit 121 and the reaction gas supply line 122 is opened and closed. There is an advantage in that gallium oxide (Ga₂O₃) can be completely reacted while minimizing remaining gallium (Ga) or ozone (O₃) by adjusting the ratio of supplied gallium (Ga) to ozone (O₃) supplied in this way.

The purge gas supply module 130 may supply a purge gas (P) to the chamber unit 300. The purge gas (P) may be an inert gas such as nitrogen (N₂) and/or argon (Ar). The purge gas supply module 130 may include a purge gas supply unit 131 that stores and/or supplies the purge gas (P), and purge gas supply lines 132 that deliver the purge gas (P) toward the chamber unit 300. At this time, the purge gas supply lines 132 may be connected to at least one of the source gas supply line 112, the reaction gas supply line 122, and the source liquid supply line 211 of the liquid supply assembly 200, which will be described later, and may discharge the source gases (S₁, S₂, S₃, and S₄) remaining inside the source gas supply line 112, the reaction gas supply line 122, the source liquid supply line 211, and the chamber unit 300, atomized source liquid (L₁), and the reaction gas (R) to the outside of the chamber unit 300.

Illustratively, the first purge gas supply line 1321 of the purge gas supply lines 132 may be connected to the reaction gas supply line 122. More specifically, the reaction gas supply line 122 of the reaction gas supply module 120 may be disposed to be connected to the first purge gas supply line 1321 out of the purge gas supply lines 132. According to such a structure, the reaction gas (R) is not mixed with the source gases (S₁, S₂, S₃, and S₄) before being injected into the interior of the chamber unit 300 from the injection unit 400, which will be described later, so that there is an advantage in that stable chemical reaction between source gases (S₁, S₂, S₃, and S₄) and reaction gas (R) and deposition on the substrate 900 are possible.

As another example, the second purge gas supply line 1322 out of the purge gas supply lines 132 may be connected to the source gas supply line 112. More specifically, the second purge gas supply line 1322 may be connected to at least one of the first source gas supply line 1121, the second source gas supply line 1122, the third source gas supply line 1123, and the fourth source gas supply line 1124. In this way, the source gas supply line 112 and the second purge gas supply line 1322 are connected so that there is an advantage in that the purge gas (P) may discharge the source gases (S₁, S₂, S₃, and S₄) remaining inside the source gas supply line 112 and the chamber unit 300 to the outside of the chamber unit 300 and enable stable deposition and thin film crystal growth.

As another example, the second purge gas supply line 1322 of the purge gas supply lines 132 may be connected to the source liquid supply line 211. At this time, the second purge gas supply line 1322 may be connected to the source liquid supply line 211 disposed between the source liquid supply unit 210, which will be described later, and the front end of the evaporation unit 220, and may be connected to the atomized source liquid supply line 211 disposed between the rear end of the evaporation unit 220 and the chamber unit 300. In this way, the source liquid supply line 211 and the second purge gas supply line 1322 are connected so that there is an advantage in that the purge gas (P) may discharge the source liquid (L₁) remaining inside the source liquid supply line 211 and the chamber unit 300 and/or the atomized source liquid (L₁) to the outside of the chamber unit 300, and enable stable deposition and thin film crystal growth.

Hereinafter, the liquid supply assembly 200 will be described.

The hybrid deposition apparatus 1 for gallium oxide according to the disclosed embodiment of the present disclosure may include a liquid supply assembly 200, and the liquid supply assembly 200 may supply at least some of the source gases (S₁, S₂, S₃, and S₄). At this time, the liquid supply assembly 200 may atomize the source liquid (L₁) to generate mist-type source gases (S₁, S₂, S₃, and S₄) and supply them to the chamber unit 300.

The liquid supply assembly 200 may include a source liquid supply unit 210 that supplies a source liquid (L₁) and an evaporation unit 220 that atomizes the source liquid (L₁). The source liquid supply unit 210 may store and/or supply the source liquid (L₁) that shares a predetermined substance with at least one of the source gases (S₁, S₂, S₃, and S₄). Illustratively, the source liquid (L₁) may be Ga(acac) 3 containing gallium (Ga), and the source liquid (L₁) may be atomized by the evaporation unit 220 to supply gallium (Ga) to the inside of the chamber unit 300. The evaporation unit 220 may be a predetermined device capable of generating ultrasonic vibration, and may receive the source liquid (L₁) from the source liquid supply unit 210 and atomize the source liquid (L₁) into a mist form. The atomized source liquid (L₁) may be supplied into the chamber unit 300 through the source liquid supply line 211 connected to the chamber unit 300 at the rear end of the evaporation unit 220.

Meanwhile, the source liquid (L₁) atomized in the mist form may react with the reaction gas (R) to form gallium oxide (Ga₂O₃) crystals on the substrate 900. At this time, the reaction gas supply module 120 and/or the liquid supply assembly 200 may each adjust supply amounts of the reaction gas (R) and the atomized source liquid (L₁) so that the remaining amounts of the source liquid (L₁) and the reaction gas (R) are minimized, thereby adjusting the ratio of gallium (Ga) supplied by the liquid supply assembly 200 to ozone (O₃) supplied by the reaction gas supply module 120.

Hereinafter, the configurations of the chamber unit 300 and the hybrid deposition apparatus 1 disposed inside the chamber unit 300, and the main pumping module 140 that discharges the source gases (S₁, S₂, S₃, and S₄), the reaction gas (R), the purge gas (P), and the source liquid (L₁) will be described.

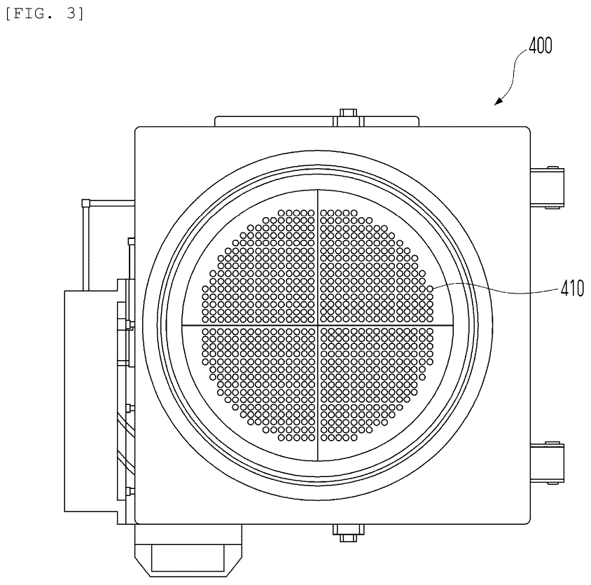

FIG. 3 is a schematic drawing for illustrating an injection unit 400, which is a component of a hybrid deposition apparatus 1 for gallium oxide according to the disclosed embodiment of the present disclosure.

Referring to FIGS. 2 and 3, the hybrid deposition apparatus 1 for gallium oxide according to the disclosed embodiment of the present disclosure may include a chamber unit 300. A substrate 900 may be disposed inside the chamber unit 300. At least one layer may be deposited on the substrate 900 to grow a thin film crystal, and a power semiconductor device or the like may be manufactured using the thin film crystal.

The hybrid deposition apparatus 1 according to the disclosed embodiment of the present disclosure may be operated in an atmospheric pressure state in which an inert gas is filled in the chamber unit 300 for stable crystal growth on a substrate 900. However, the configuration in which the operating pressure of the chamber unit 300 of the hybrid deposition apparatus 1 is atmospheric pressure is only an exemplary configuration, and a configuration in which the chamber region 180 is in a vacuum state or a low pressure state may also be included in the spirit of the present disclosure.

The chamber unit 300 may be connected to the gas supply assembly 100 and the liquid supply assembly 200. More specifically, the chamber unit 300 may be connected to the gas supply assembly 100 and receive source gases (S₁, S₂, S₃, and S₄), reaction gas (R), and purge gas (P) simultaneously or sequentially, and may be connected to the liquid supply assembly 200 and receive atomized source liquid L₁. A product (for example, Ga₂O₃ or AlGaOₓ for resolving lattice mismatch) generated by a chemical reaction between the source gases (S₁, S₂, S₃, and S₄) or the atomized source liquid (L₁) and the reaction gas (R) may be deposited on a substrate 900 disposed inside the chamber unit 300 to a preset thickness.

At this time, the gas supply assembly 100 and the liquid supply assembly 200 may be coupled to the upper side of the chamber unit 300. More specifically, the source gas supply line 112 of the gas supply assembly 100, the purge gas supply lines 132 connected to the reaction gas supply line 122, and the source liquid supply line 211 may be coupled to the upper side of the chamber unit 300. Accordingly, the source gases (S₁, S₂, S₃, and S₄), the reaction gas (R), and the purge gas (P) supplied from the gas supply assembly 100, or the source liquid (L₁) supplied from the liquid supply assembly 200 may be vertically sprayed toward one surface (e.g., the upper surface) of the substrate 900 disposed inside the chamber unit 300.

When performing deposition using a conventional mist-chemical vapor deposition (Mist-CVD) method, a thin film is deposited by flowing mist from one side of the upper surface of the substrate 900 to the other side thereof. However, when using such a method, a problem occurs in that the mist flowing on the upper surface of the substrate 900 is not deposited at a uniform height, which may cause defects in the manufactured wafer and the semiconductor produced accordingly. In order to solve such a problem, the hybrid deposition apparatus 1 for gallium oxide according to the disclosed embodiment of the present disclosure has the advantage of enabling uniform thin film crystal growth by vertically injecting gas and/or liquid necessary for forming a thin film crystal onto the upper surface of the substrate 900.

In addition, in order to uniformly inject gas and/or liquid onto the substrate 900, the hybrid deposition apparatus 1 for gallium oxide according to the disclosed embodiment of the present disclosure may further include an injection unit 400 formed inside the chamber unit 300. The injection unit 400 may include a plurality of fine injection nozzles 410. The injection unit 400 may be connected to the supply lines (e.g., the source gas supply line and/or the source liquid supply line) of the gas supply assembly 100 and the liquid supply assembly 200 to inject at least one of the source gases (S₁, S₂, S₃, and S₄), the reaction gas (R), the purge gas (P), and the (atomized) source liquid (L₁) into the chamber unit 300, and the plurality of injection nozzles 410 may be disposed so as to cover the upper surface area of the substrate 900. In another embodiment, the plurality of injection nozzles 410 may be disposed to cover the entire cross-sectional area of the chamber unit 300, but may also be controlled so that it is operated as much as a region corresponding to the area of the substrate 900 disposed inside the chamber unit 300.

In some cases, each of the plurality of injection nozzles 410 included in the injection unit 400 may be selectively operated when the substrate 900 moves in parallel inside the chamber unit 300. Although it is not illustrated in detail in the drawings of the present disclosure, the substrate 900 may move horizontally inside the chamber unit 300. When the substrate 900 moves horizontally inside the chamber unit 300, the injection nozzles 410 may perform injection of gas and/or liquid depending on the position of the substrate 900. Accordingly, time-division deposition and/or space-division deposition may be performed, and there is an advantage of enabling uniform and stable thin film crystal deposition.

The hybrid deposition apparatus 1 for gallium oxide according to the disclosed embodiment of the present disclosure may include a substrate adjustment unit 600. The substrate adjustment unit 600 may support a lower portion of a substrate 900 and rotate the substrate 900 in one direction. For example, the substrate adjustment unit 600 may rotate a susceptor 500 disposed at a lower portion of the substrate 900, and the substrate 900 seated on the susceptor 500 may be rotated together with the susceptor 500. Since the substrate 900 may be rotated by the substrate adjustment unit 600, there is an advantage in that more uniform thin film deposition is possible.

In addition, the hybrid deposition apparatus 1 for gallium oxide according to the disclosed embodiment of the present disclosure may further include a heating unit 700. For example, the heating unit 700 may adjust the temperature inside the substrate 900 and the chamber unit 300, and may be formed on the bottom of the substrate adjustment unit 600. As another example, the heating unit 700 may be formed on the bottom of the susceptor 500 to heat or cool the susceptor 500 and the substrate 900 so that they reach a target temperature. For example, the heating unit 700 may be heated to a maximum of 1,000° C. to 1, 200° C. and transfer thermal energy to the substrate 900 and the chamber unit 300. There is an advantage in that easy deposition of a layer (epilayer) is possible in a high-temperature environment by the heating unit 700.

In addition, the hybrid deposition apparatus 1 for gallium oxide according to the disclosed embodiment of the present disclosure may include a main pumping module 140. The main pumping module 140 may discharge source gases (S₁, S₂, S₃, and S₄), reaction gas (R), purge gas (P), and (atomized) source liquid (L₁) remaining inside the chamber unit 300 to the outside by providing negative pressure. For example, the main pumping module 140 includes a main pump 141, and the main pump 141 may generate a pressure difference that forms a fluid flow from the chamber unit 300 side toward the discharge line 142 side by providing negative pressure. Accordingly, there are advantages in that gas and/or liquid remaining inside the chamber unit 300 may be easily discharged to the discharge line 142, and stable and precise thin film crystal deposition is possible.

Hereinafter, a gallium oxide thin film deposited using the hybrid deposition apparatus 1 for gallium oxide according to the disclosed embodiment of the present disclosure will be described.

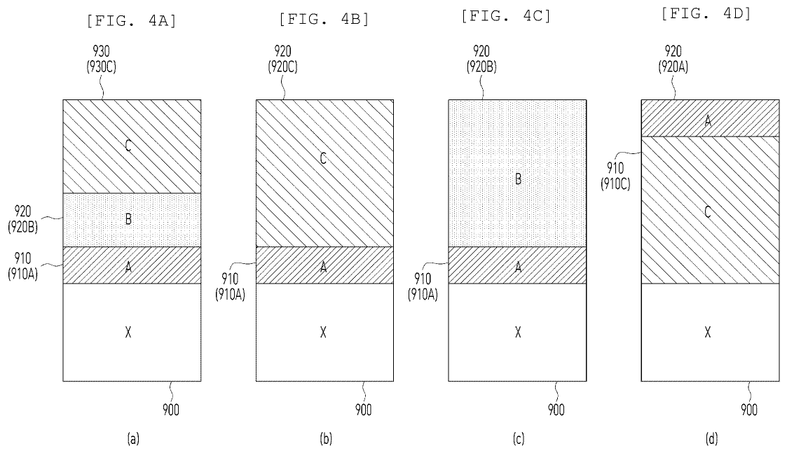

FIGS. 4A through 4D show various examples of gallium oxide thin films grown using a hybrid deposition apparatus 1 for gallium oxide according to the disclosed embodiment of the present disclosure.

Referring to FIG. 2 and FIGS. 4A-4D, the hybrid deposition apparatus 1 for gallium oxide according to the disclosed embodiment of the present disclosure may grow a thin film crystal of a plurality of layers on a substrate 900 using at least two deposition methods. For example, the gas supply assembly 100 and the liquid supply assembly 200 of the hybrid deposition apparatus 1 for gallium oxide may be selectively operated to grow a plurality of layers on the substrate 900 through at least two of an atomic layer deposition (ALD) method, a metal-organic chemical vapor deposition (MOCVD) method, and a mist-chemical vapor deposition (Mist-CVD) method.

First, a substrate 900 is disposed inside the chamber unit 300. For example, the substrate 900 may be an n-type β-gallium oxide (β-Ga₂O₃) substrate, a silicon substrate, or a silicon carbide substrate. As another example, the substrate 900 may be a sapphire substrate of aluminum oxide (Al₂O₃). When the sapphire substrate of aluminum oxide (Al₂O₃) is used, crystal mismatch (layer mismatch) may occur between thin film crystal layers, but the mismatch problem can be resolved by forming a superlattice using aforementioned trimethylaluminum (TMA).

Thereafter, a first layer 910 may be deposited on the substrate 900. For example, the first layer 910 may be a β-gallium oxide (β-Ga₂O₃) layer, and the first layer 910 may be deposited and formed using an atomic layer deposition (ALD) method. When the first layer 910 is deposited using an atomic layer deposition (ALD) method, the atomic layer-deposited first layer 910A may be formed to a thickness of about 10 nm to 30 nm in a temperature range of 100° C. to 350° C. When the first layer 910 is deposited using an atomic layer deposition (ALD) method, the source gas supply module 110, the reaction gas supply module 120, and the purge gas supply module 130 of the gas supply assembly 100 may operate simultaneously or sequentially, and one atomic layer may be deposited per cycle. Accordingly, a thin, precise, thin film layer may be formed.

As another example, the first layer 910 may be a β-gallium oxide (β-Ga₂O₃) layer, and the first layer 910 may be deposited and formed using a mist-chemical vapor deposition (Mist-CVD) method. When the first layer 910 is deposited using a mist-chemical vapor deposition (Mist-CVD) method, the mist chemical vapor-deposited first layer 910C may be formed to a thickness of about 5 μm to 12 μm in a temperature range of 600° C. to 1,000° C. When the first layer 910 is deposited using a mist-chemical vapor deposition (Mist-CVD) method, a source liquid (L₁) atomized by an evaporation unit 220 of a liquid supply assembly 200 may be supplied into the chamber unit 300, and a thin film layer may be formed. If necessary, the reaction gas supply module 120 of the gas supply assembly 100 may operate together to adjust the Ga/O ratio for producing gallium oxide (Ga₂O₃).

Thereafter, a second layer 920 may be deposited on the first layer 910. For example, the second layer 920 may be a β-gallium oxide (β-Ga₂O₃) layer, and the second layer 920 may be deposited using a method that is different from the method used when depositing the first layer 910. For example, when the first layer 910 is deposited on the substrate 900 using an atomic layer deposition (ALD) method, the second layer 920 may be deposited using any one of a metal-organic chemical vapor deposition (MOCVD) method and a mist-chemical vapor deposition (Mist-CVD) method. When the second layer 920 is deposited using the metal-organic chemical vapor deposition (MOCVD) method, the metal-organic chemical vapor deposited second layer 920B may be formed to a thickness of about 1 μm to 3 μm in a temperature range of 400° C. to 1,000° C. As another example, when the second layer 920 is deposited using the metal-organic chemical vapor deposition (MOCVD) method, the metal-organic chemical vapor deposited second layer 920B may be formed to a thickness of about 5 μm to 12 μm in a temperature range of 400° C. to 1,000° C. When the second layer 920 is deposited using the metal-organic chemical vapor deposition (MOCVD) method, the source gases (S₁, S₂, S₃, and S₄) supplied by the source gas supply module 110 of the gas supply assembly 100 and the reaction gas (R) supplied by the reaction gas supply module 120 may be mixed and supplied into the chamber unit 300, and a thin film layer may be formed.

As another example, when the second layer 920 is deposited using a mist-chemical vapor deposition (Mist-CVD) method, the mist chemical vapor-deposited second layer 920C may be formed to a thickness of about 5 μm to 12 μm in a temperature range of 600° C. to 1,000° C.

As another example, when the first layer 910 is deposited using a mist-chemical vapor deposition method, the second layer 920 may be deposited using an atomic layer deposition method. The atomic layer-deposited second layer 920A may be formed to a thickness of about 10 nm to 30 nm in a temperature range of 100° C. to 350° C.

Thereafter, a third layer 930 may be additionally deposited on the second layer 920. For example, the third layer 930 may be a β-gallium oxide (β-Ga₂O₃) layer, and the third layer 930 may be deposited using a method that is different from the method used when depositing the first layer 910 and the second layer 920. For example, when the first layer 910 is deposited on the substrate 900 using an atomic layer deposition (ALD) method and the second layer 920 is deposited on the first layer 910 using a metal-organic chemical vapor deposition (MOCVD) method, the third layer 930 may be deposited using a mist-chemical vapor deposition (Mist-CVD) method. When the third layer 930 is deposited using a mist-chemical vapor deposition (Mist-CVD) method, the mist-chemical vapor deposited third layer 930C may be formed to a thickness of about 3 μm to 10 μm in a temperature range of 600° C. to 1,000° C.

In various forms in which the gallium oxide thin film is deposited as described above, if a layer using the atomic layer deposition method is represented as A, a layer using the metal-organic chemical vapor deposition method is represented as B, and a layer using the mist-chemical vapor deposition method is represented as C, an embodiment in which A layer-B layer-C layer are deposited and formed on a substrate 900 (FIG. 4A), an embodiment in which A layer-C layer are deposited and formed on a substrate 900 (FIG. 4B), an embodiment in which A layer-B layer are deposited and formed on a substrate 900 (FIG. 4C), and an embodiment in which C layer-A layer are deposited and formed on a substrate 900 (FIG. 4D) are possible. However, the embodiments illustrated in FIGS. 4A-4D are exemplary, and a thin film deposition structure having a deposition of more layers and a deposition order different from the disclosed deposition order is also possible, if necessary.

As described above, there is an advantage in that an integrated high-voltage, high-output semiconductor having a high band gap compared to a conventional silicon semiconductor can be manufactured by using the hybrid deposition apparatus 1 for gallium oxide according to the disclosed embodiment of the present disclosure capable of growing and depositing a gallium oxide thin film crystal on a substrate 900.

In addition, there is an advantage in that a semiconductor meeting required specifications can be manufactured by using the hybrid deposition apparatus 1 for gallium oxide capable of applying various deposition methods when manufacturing a semiconductor using gallium oxide as a material.

In addition, there is an advantage in that the shortcomings of each deposition method can be supplemented by using the hybrid deposition apparatus 1 for gallium oxide capable of applying various deposition methods.

Hereinafter, a method for hybrid depositing according to a disclosed embodiment of the present disclosure using the hybrid deposition apparatus for gallium oxide described above will be described. In describing the method for hybrid depositing using the hybrid deposition apparatus for gallium oxide according to the disclosed embodiment of the present disclosure, any content overlapping with the hybrid deposition apparatus for gallium oxide described above will be briefly mentioned, or the description thereof will be omitted.

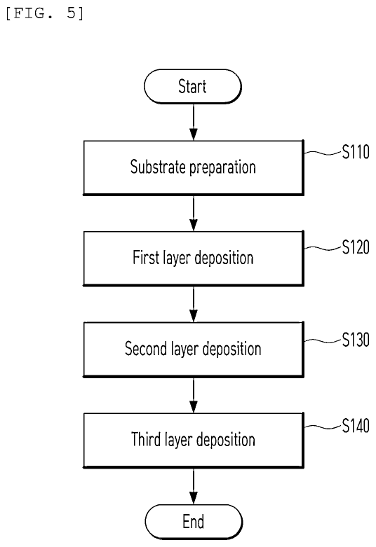

FIGS. 4A-4D show various examples of gallium oxide thin films grown using a hybrid deposition apparatus for gallium oxide according to the disclosed embodiment of the present disclosure, and FIG. 5 is a schematic flowchart of a method for hybrid depositing using a hybrid deposition apparatus for gallium oxide according to the disclosed embodiment of the present disclosure.

Referring to FIGS. 1 to 5, the method for hybrid depositing using the hybrid deposition apparatus for gallium oxide according to the disclosed embodiment of the present disclosure may include a substrate preparation step (S110), a first layer deposition step (S120), and a second layer deposition step (S130).

In the method for hybrid depositing using the hybrid deposition apparatus for gallium oxide according to the disclosed embodiment of the present disclosure, the substrate preparation step (S110) may mean disposing a substrate on which a thin film crystal is to be grown inside a chamber unit. The substrate may be at least one of an n-type β-gallium oxide (β-Ga₂O₃) substrate, a silicon substrate, a silicon carbide (SiC) substrate, and an aluminum oxide (Al₂O₃) sapphire substrate.

Thereafter, a first layer deposition step (S120) may be performed. In the first layer deposition step (S120), a first layer may be deposited on the substrate by any one of a gas supply assembly and a liquid supply assembly. At this time, the first layer may be thin film-deposited by an atomic layer deposition (ALD) method, and when the first layer is thin film-deposited by the atomic layer deposition method, the gas supply assembly may be operated.

Thereafter, a second layer deposition step (S130) may be performed. In the second layer deposition step (S130), a second layer may be deposited on the first layer by any one of the gas supply assembly and the liquid supply assembly. Meanwhile, the first layer and the second layer may be deposited through different deposition methods. For example, the first layer deposition step (S120) may be performed by an atomic layer deposition method to deposit the first layer on the substrate, and the second layer deposition step (S130) may be performed by any one of a metal-organic chemical vapor deposition method and a mist-chemical vapor deposition method to deposit the second layer on the substrate.

In addition, a third layer deposition step (S140) may be performed. In the third layer deposition step (S140), a third layer may be deposited on the second layer by the liquid supply assembly. Meanwhile, the third layer may be deposited through a deposition method that is different from those of the first layer and the second layer. For example, the first layer deposition step (S120) may be performed by an atomic layer deposition method to deposit the first layer on the substrate, the second layer deposition step (S130) may be performed by a metal-organic chemical vapor deposition method to deposit the second layer on the first layer, and the third layer deposition step (S140) may be performed by a mist-chemical vapor deposition method to deposit the third layer on the second layer.

Meanwhile, since the thickness, formation temperature, etc. for each layer have been described together in the process of explaining the hybrid deposition apparatus for gallium oxide according to the disclosed embodiment of the present disclosure, a detailed description of each layer will be omitted.

As another example, when the first layer deposition step (S120) is performed by a mist-chemical vapor deposition method to deposit the first layer on the substrate, the second layer deposition step (S130) may be performed by an atomic layer deposition method to deposit the second layer on the first layer. In this way, there are advantages in that thin film deposition and crystal growth can be performed on the substrate by applying an efficient method for manufacturing a high-performance semiconductor, and a high-quality semiconductor to which a plurality of deposition methods are applied using the method for hybrid depositing according to the disclosed embodiment of the present disclosure can be manufactured.

In addition, since the method for hybrid depositing according to the disclosed embodiment of the present disclosure is performed using the hybrid deposition apparatus for gallium oxide according to the disclosed embodiment of the present disclosure, it shares the advantages of the hybrid deposition apparatus.

Hereinafter, a hybrid deposition apparatus for gallium oxide according to another embodiment of the present disclosure will be described. In describing the hybrid deposition apparatus for gallium oxide according to another embodiment of the present disclosure, the same configuration and structure as the aforementioned hybrid deposition apparatus for gallium oxide according to one embodiment of the present disclosure will be briefly mentioned or the description thereof will be omitted.

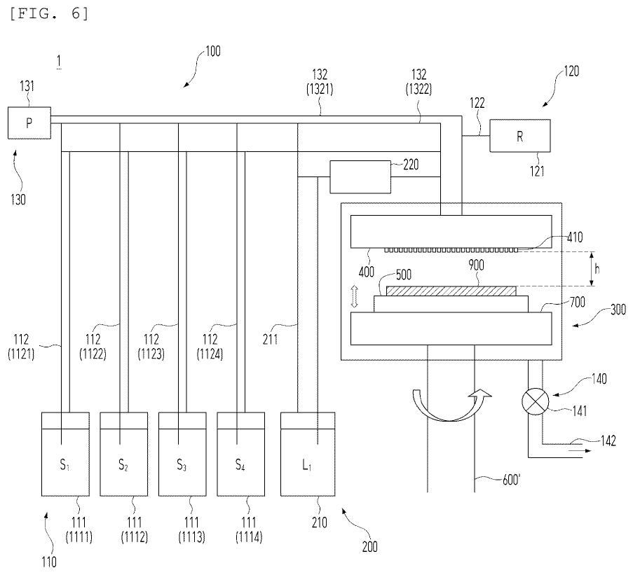

FIG. 6 is a conceptual diagram of a hybrid deposition apparatus 1 for gallium oxide according to another embodiment of the present disclosure.

Referring to FIG. 6, the hybrid deposition apparatus 1 for gallium oxide according to another embodiment of the present disclosure includes the same gas supply assembly 100, liquid supply assembly 200, chamber unit 300, and injection unit 400 as the hybrid deposition apparatus 1 for gallium oxide described above.

In addition, the hybrid deposition apparatus 1 for gallium oxide according to another embodiment of the present disclosure provides a more specific structure for applying various deposition methods to one hybrid deposition apparatus for gallium oxide. For example, an atomic layer deposition (ALD) method, which is one of the deposition methods, has a slow deposition rate, but has an advantage in that crystals of the deposition-formed layer are relatively fine. As another example, a metal-organic chemical vapor deposition (MOCVD) method, which is another of the deposition methods, has an advantage in that crystals of the deposition-formed layer are not relatively fine, but they have fast deposition rates.

However, when depositing a layer using an atomic layer deposition (ALD) method, the source gases (S₁, S₂, S₃, and S₄) and/or the source liquid (L₁) must be injected and deposited under relatively low pressure and low temperature conditions, and when depositing a layer using a metal-organic chemical vapor deposition (MOCVD) method, the source gases (S₁, S₂, S₃, and S₄) and/or the source liquid (L) must be injected and deposited under relatively high pressure and high temperature conditions. In order for a layer to be deposited on the substrate 900 in a uniform and stable shape and structure, the optimal deposition conditions may be different depending on which deposition method is used.

Since conventional deposition equipment applied one deposition method, conventional deposition equipment was operated in a form in which the conditions inside the chamber unit 300 were maintained constant. In addition, even if a plurality of deposition methods are applied on one substrate using a plurality of deposition equipment that only apply different deposition methods, there is a concern that the crystal of the deposited layer may be deformed or contamination by the external environment may occur when moving from one deposition equipment to another.

In order to solve such problems, the hybrid deposition apparatus 1 for gallium oxide according to another (disclosed) embodiment of the present disclosure may further include a substrate adjustment unit 600′ that supports a lower portion of the substrate 900 and rotates the substrate 900 in one direction. At this time, the substrate adjustment unit 600′ of the hybrid deposition apparatus 1 for gallium oxide according to another embodiment of the present disclosure may not only rotate the substrate 900, but also elevate the substrate 900 to adjust the position of the substrate 900 within the chamber unit 300. For example, the substrate adjustment unit 600′ may be raised or lowered to adjust the height h of the substrate 900 within the chamber unit 300. As illustrated in FIG. 6, the height h of the substrate 900 may mean a distance between the ends of a plurality of injection nozzles 410, which are a component of the injection unit 400, and the upper surface of the substrate 900.

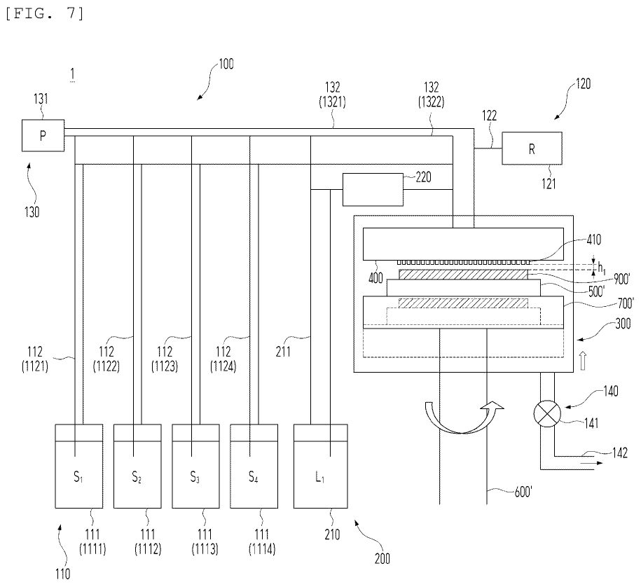

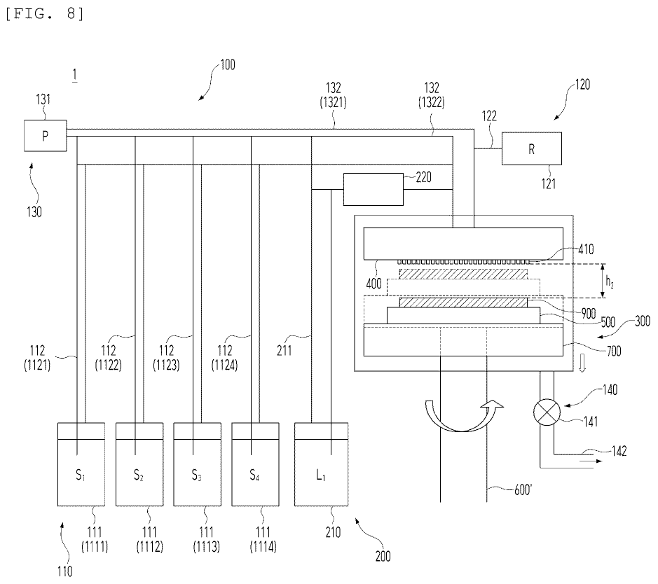

FIG. 7 is a diagram for explaining a process of preparing a substrate 900 in a first state in order to deposit a first layer by a first deposition method in a hybrid deposition apparatus 1 for gallium oxide according to another embodiment of the present disclosure, and FIG. 8 is a diagram for explaining a process of preparing a substrate 900 in a second state in order to deposit a second layer by a second deposition method in a hybrid deposition apparatus 1 for gallium oxide according to another embodiment of the present disclosure.

Referring to FIG. 7, the substrate adjustment unit 600′ may raise the heating unit 700 and the susceptor 500, and accordingly, the substrate 900 seated on the susceptor 500 is also raised and moved to the first position or the first height (h₁). In addition, the heating unit 700 may be controlled by a control unit (not shown) to heat the substrate 900 to a first temperature range (T₁). When the substrate 900 is prepared in the first state in this way, the injection nozzles 410 may inject the source gases (S₁, S₂, S₃, and S₄) or the atomized source liquid (L₁) toward the upper surface of the substrate 900 under the first process pressure (P₁) using the first deposition method, and the first layer may be deposited on the substrate 900.

More specifically, the first deposition method may be an atomic layer deposition (ALD) method, and the first temperature range (T₁) included in the first state may be 100° C. to 350° C. In addition, the first layer deposited using the first deposition method may have a thickness of 10 nm to 30 nm, and the first process pressure (P₁) according to the first deposition method may be 0.5 to 20 torr. The first layer deposited using the first deposition method may form an amorphous buffer layer.

Referring to FIG. 8, after the first layer is deposited on the substrate 900, the substrate adjustment unit 600′ may lower the heating unit 700 and the susceptor 500, and accordingly, the substrate 900 seated on the susceptor 500 is also lowered and moved to the second position or the second height (h₂). In addition, the heating unit 700 may be controlled by a control unit (not shown) to heat the substrate 900 to a second temperature range (T₂). When the substrate 900 is prepared in the second state in this way, the injection nozzles 410 may inject the source gases (S₁, Ω, S₃, and S₄) or the atomized source liquid (L₁) toward the upper surface of the substrate 900 (more specifically, the upper surface of the first layer) under the second process pressure (P₁) using the second deposition method, and the second layer may be deposited on the substrate 900 (more specifically, on the first layer).

At this time, the second deposition method may be a metal-organic chemical vapor deposition (MOCVD) method, and due to the difference in the optimal conditions of the metal-organic chemical vapor deposition (MOCVD) method and the atomic layer deposition (ALD) method, the second height (h₂) is formed to be greater than the first height (h₁), the second temperature range (T₂) is formed to be higher than the first temperature range (T₁), and the second process pressure (P₂) may also be set to be higher than the first process pressure (P₁). In addition, the second layer may be formed to a thickness greater than the thickness of the first layer.

More specifically, the second temperature range (T₂) included in the second state may be 400° C. to 1,000° C. In addition, the second layer deposited using the second deposition method may have a thickness of 1 μm to 10 μm, and the second process pressure (P₂) according to the second deposition method may be 30 torr to 500 torr. The second layer deposited using the second deposition method may form a single crystal layer.

Meanwhile, the first layer may act as an amorphous buffer layer so that the second layer of the single crystal may be more easily stacked and formed on the substrate 900, and accordingly, there is an advantage in that the second layer may be stably deposited and grown.

If necessary, a process of cleaning the interior of the chamber unit 300 may be performed before and after depositing the second layer. In particular, after depositing the second layer, there is a high possibility that the source gases (S₁, S₂, S₃, and S₄) or the source liquid (L₁) will remain inside the chamber unit 300 due to the high-pressure injection of the source gases (S₁, S₂, S₃, and S₄) or the source liquid (L₁), and a cleaning step of discharging the remaining source gases (S₁, S₂, S₃, and S₄) or the source liquid (L₁) to the outside may be performed. Accordingly, there are advantages in that the reliability of the power semiconductor completed by depositing a layer on the substrate 900 may be improved, and the durability of the hybrid deposition apparatus 1 for gallium oxide is improved.

In this way, since the hybrid deposition apparatus 1 for gallium oxide according to another embodiment of the present disclosure includes a substrate adjustment unit 600′ capable of elevating a substrate 900, and a heating unit 700, the state (temperature, height, etc.) of the inside of the chamber unit 300 and the substrate 900 may be changed to correspond to the optimal conditions of the deposition method used to deposit each layer. Accordingly, there are advantages in that a plurality of layers may be stably deposited using a plurality of deposition methods in one apparatus, the production speed of power semiconductors manufactured by depositing and growing layers on a substrate is improved, and the reliability of power semiconductors is improved by minimizing the inflow of foreign substances during the deposition process.

Hereinafter, a method for hybrid depositing using the hybrid deposition apparatus 1 for gallium oxide according to another embodiment of the present disclosure will be described. In describing a method for hybrid depositing according to another embodiment of the present disclosure, the same configuration and structure as the method for hybrid depositing according to one embodiment of the present disclosure described above will be briefly mentioned or a description thereof will be omitted.

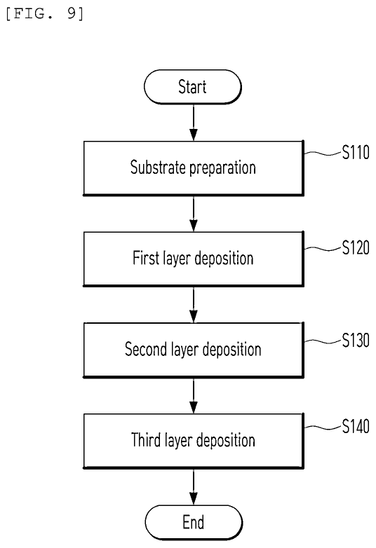

FIG. 9 is a schematic flowchart of a method for hybrid depositing using a hybrid deposition apparatus 1 for gallium oxide according to another embodiment of the present disclosure.

Referring to FIG. 9, a method for hybrid depositing using a hybrid deposition apparatus 1 for gallium oxide according to a disclosed embodiment of the present disclosure includes a substrate preparation step (S210), a first layer deposition step (S230), and a second layer deposition step (S260), similarly to the method for hybrid depositing described above. Since the substrate preparation step (S210) in the present embodiment is identical to the substrate preparation step (S110) in the above-described embodiment, the first layer deposition step (S230) in the present embodiment is identical to the first layer deposition step (S120) in the above-described embodiment, and the second layer deposition step (S260) in the present embodiment is identical to the second layer deposition step (S130) in the above-described embodiment, detailed descriptions thereof will be omitted.

Meanwhile, the method for hybrid depositing according to another embodiment of the present disclosure may further include a deposition preparation step (S220, S250) prior to each deposition step (S230, S260). For example, the deposition preparation step (S220, S250) may include a first layer deposition preparation step (S220) and a second layer deposition preparation step (S250).

The first layer deposition preparation step (S220) may be performed between the substrate preparation step (S210) and the first layer deposition step (S230). The first layer deposition preparation step (S220) may be a step of preparing a state of the substrate with an optimal condition of a first deposition method used to deposit the first layer on the substrate. For example, the first deposition method may be an atomic layer deposition (ALD) method, and a substrate adjustment unit, which is a component of a hybrid deposition apparatus for gallium oxide in the first layer deposition preparation step (S220), may elevate (more specifically, raise) a heating unit and a susceptor to adjust a substrate seated on the susceptor to a first height. At this time, the ‘height’ may mean a vertical distance from the ends of the injection nozzles, which are detailed components of the injection unit, to the upper surface of the substrate. In addition, the heating unit in the first layer deposition preparation step (S220) may be heated so that the substrate reaches a first temperature range. Accordingly, the substrate and chamber unit in the first layer deposition preparation step (S220) may be prepared in the first state.

When the substrate is prepared in the first state through the first layer deposition preparation step (S220), the injection unit in the first layer deposition step (S230) may inject the source gas or source liquid toward the substrate at the first process pressure to deposit an amorphous first layer as thick as the first thickness. For example, the first layer may be a buffer layer, and the first layer may serve to buffer the second layer so that the second layer may be easily deposited and grown on the substrate. Since the first temperature range, the first process pressure, and the first thickness which are for depositing the first layer have already been described in the hybrid deposition apparatus for gallium oxide, detailed descriptions thereof will be omitted.

The second layer deposition preparation step (S250) may be performed between the first layer deposition step (S230) and the second layer deposition step (S260). The second layer deposition preparation step (S250) may be a step of preparing a state of the substrate with an optimal condition of a second deposition method used to deposit a second layer on the substrate (more specifically, on the first layer). For example, the second deposition method may be a metal-organic chemical vapor deposition (MOCVD) method, and a substrate adjustment unit, which is a component of a hybrid deposition apparatus for gallium oxide in the second layer deposition preparation step (S250), may elevate (more specifically, lower) a heating unit and a susceptor to adjust a substrate seated on the susceptor to a second height. In addition, the heating unit in the second layer deposition preparation step (S250) may be heated so that the substrate reaches a second temperature range. Accordingly, the substrate and the chamber unit in the second layer deposition preparation step (S250) may be prepared in the second state.

When the substrate is prepared in the second state through the second layer deposition preparation step (S250), the injection unit in the second layer deposition step (S260) may inject the source gas or source liquid toward the substrate at the second process pressure to deposit the second layer of the single crystal as thick as the second thickness. For example, the second layer may be a single crystal layer, and the second layer may be laminated on the first layer, which is a buffer layer. Since the second temperature range, the second process pressure, and the second thickness which are for depositing the second layer have already been described in the hybrid deposition apparatus for gallium oxide, detailed descriptions thereof will be omitted.

In addition, a cleaning step (S240) may be further included between the first layer deposition step (S230) and the second layer deposition step (S260). The cleaning step (S240) may be a process for discharging the source gases (S₁, S₂, S₃, and S₄) or the source liquid (L₁) remaining in the chamber unit due to the first layer deposition step (S230) to the outside. In the cleaning step (S240), the substrate adjustment unit, which is a component of the hybrid deposition apparatus for gallium oxide, may elevate (more specifically, raise) the heating unit and the susceptor to adjust the substrate seated on the susceptor to a third height. At this time, the third height may be the same as the first height or may be smaller than the first height. That is, the substrate in the cleaning step (S240) may be raised to a position higher than that in the first layer deposition step (S230). In addition, the heating unit in the cleaning step (S240) may be turned off. When the substrate is adjusted to the third height, a purge gas may be supplied through the injection unit, or gas and/or liquid remaining inside the chamber unit 300 can be easily discharged to the discharge line through the operation of the main pumping module.

Meanwhile, in the cleaning step (S240), since the substrate adjustment unit enters the chamber unit to the maximum extent as well as the internal space of the chamber unit, the source gases (S₁, S₂, S₃, and S₄) and/or the source liquid (L₁) that may remain on the surface of the substrate adjustment unit can be removed, and the overall hygiene of the hybrid deposition apparatus for gallium oxide can be improved.

If necessary, a third layer deposition step (not shown) of additionally depositing a third layer on the second layer using a third deposition method (for example, a Mist-CVD method) may be further included after the second layer deposition step (S260). In addition, a second cleaning step (not shown) of cleaning the interior of the chamber unit may be further performed between the second layer deposition step (S260) and the third layer deposition step, and a third adjustment step (not shown) of preparing (for example, adjusting the substrate to a third height) the substrate in a third state to achieve an optimal condition for using the third deposition method may be performed.

Although the preferred embodiments of the present disclosure have been described above, the present disclosure is not limited thereto, and various modifications and implementations may be made within the scope of the claims, the detailed description of the invention, and the scope of the attached drawings, it goes without saying that these also fall within the scope of the present disclosure.

### INDUSTRIAL APPLICABILITY

The present disclosure is for providing a hybrid deposition apparatus for gallium oxide that forms a crystal layer using at least two deposition methods to manufacture a wafer, and a method for hybrid depositing using the same.

What is claimed is:

1. A hybrid deposition apparatus for gallium oxide comprising:
a gas supply assembly for supplying a source gas, a reaction gas, and a purge gas;
a liquid supply assembly for supplying at least a portion of the source gas; and
a chamber unit which is connected to the gas supply assembly and the liquid supply assembly and has a substrate disposed therein.

2. The hybrid deposition apparatus for gallium oxide of claim 1, wherein the gas supply assembly comprises a source gas supply module for supplying the source gas, a reaction gas supply module for supplying the reaction gas, a purge gas supply module for supplying the purge gas, and a main pumping module for providing negative pressure.

3. The hybrid deposition apparatus for gallium oxide of claim 2, wherein the source gas supply module comprises:
a first source gas supply unit supplying a first source gas; and
a second source gas supply unit supplying a second source gas different from the first source gas, and
at least one of the first source gas and the second source gas includes trimethyl gallium (TMG).

4. The hybrid deposition apparatus for gallium oxide of claim 3, wherein the reaction gas supply module is disposed to be connected to the purge gas supply module, and the reaction gas supply module receives oxygen (O₂) from the outside to generate ozone (O₃) and supply it to the chamber unit.

5. The hybrid deposition apparatus for gallium oxide of claim 4, wherein the reaction gas supply module adjusts a ratio of gallium supplied from the source gas supply module and the liquid supply assembly to ozone supplied to the chamber unit.

6. The hybrid deposition apparatus for gallium oxide of claim 4, wherein the liquid supply assembly comprises a source liquid supply unit that supplies a source liquid, and an evaporation unit that atomizes the source liquid.

7. The hybrid deposition apparatus for gallium oxide of claim 1, wherein the gas supply assembly and the liquid supply assembly are coupled to an upper side of the chamber unit, and the source gas, reaction gas, purge gas supplied from the gas supply assembly, or a source liquid supplied from the liquid supply assembly is injected vertically toward one surface of the substrate disposed inside the chamber unit.

8. The hybrid deposition apparatus for gallium oxide of claim 7, comprising an injection unit comprising a plurality of injection nozzles which are formed inside the chamber unit and connected to the gas supply assembly and the liquid supply assembly to inject at least one of the source gas, the reaction gas, the purge gas, and the source liquid onto one surface of the substrate.

9. The hybrid deposition apparatus for gallium oxide of claim 1, further comprising a substrate adjustment unit that supports a lower portion of the substrate and rotates the substrate in one direction.

10. The hybrid deposition apparatus for gallium oxide of claim 9, further comprising a heating unit which is formed on a bottom of the substrate adjustment unit and adjusts temperatures inside the substrate and the chamber unit.

11. The hybrid deposition apparatus for gallium oxide of claim 10, wherein the substrate adjustment unit adjusts a position of the substrate within the chamber unit by elevating the substrate.

12. The hybrid deposition apparatus for gallium oxide of claim 11, wherein the substrate adjustment unit prepares the substrate in a first state in order to deposit a first layer on the substrate by a first deposition method, the substrate adjustment unit elevates the substrate and moves it to a first height, the heating unit heats the substrate to a first temperature range, the first deposition method includes an atomic layer deposition method, and the first layer is an amorphous buffer layer.

13. The hybrid deposition apparatus for gallium oxide of claim 12, wherein the substrate adjustment unit prepares the substrate in a second state in order to deposit a second layer on the first layer by a second deposition method, the substrate adjustment unit lowers the substrate and moves the substrate to a second height, the heating unit heats the substrate to a second temperature range, the second deposition method includes a metal-organic chemical vapor deposition method, the second layer is a single crystal layer, the second height is formed to be greater than the first height, and the second temperature range is formed to be higher than the first temperature range.

14. The hybrid deposition apparatus for gallium oxide of claim 1, wherein the gas supply assembly and the liquid supply assembly operate selectively to grow a plurality of layers on the substrate through at least two of an atomic layer deposition (ALD) method, a metal-organic chemical vapor deposition (MOCVD) method, and a mist-chemical vapor deposition (Mist-CVD) method.

15. A method for hybrid depositing using the hybrid deposition apparatus for gallium oxide according to claim 1, the method for hybrid depositing comprising:
a substrate preparation step of disposing a substrate to be grown inside a chamber unit;
a first layer deposition step of depositing a first layer on the substrate by any one of the gas supply assembly and the liquid supply assembly; and
a second layer deposition step of depositing a second layer on the first layer by any one of the gas supply assembly and the liquid supply assembly,
wherein the first layer and the second layer are deposited through different deposition methods.

16. The method for hybrid depositing of claim 15, wherein the first layer deposition step is performed by an atomic layer deposition (ALD) method, which is a first deposition method, and the second layer deposition step is performed by any one of a metal-organic chemical vapor deposition (MOCVD) method and a mist-chemical vapor deposition (Mist-CVD) method, which are second deposition methods.

17. The method for hybrid depositing of claim 16, further comprising:
a first layer deposition preparation step of preparing the substrate in a first state, which is an optimal condition for the first deposition method, by a substrate adjustment unit before the first layer deposition step; and
a second layer deposition preparation step of preparing the substrate in a second state, which is the optimal condition for the second deposition method, by the substrate adjustment unit before the second layer deposition step.

18. The method for hybrid depositing of claim 17, wherein the first state includes at least one of a first height and a first temperature range, the second state includes at least one of a second height and a second temperature range, the second height is formed to be greater than the first height, and the second temperature range is formed to be higher than the first temperature range.

19. The method for hybrid depositing of claim 15, further comprising a third layer deposition step of depositing a third layer on the second layer by the liquid supply assembly,
wherein the third layer deposition step is performed by a mist-chemical vapor deposition method.
